(19) United States
(12) Patent Application Publication
(10) Pub. No.: US 2014/0008110 A1
(43) Pub. Date: Jan. 9, 2014

(54) PCB MANUFACTURING PROCESS AND STRUCTURE

(71) Applicants: Shawn X. Arnold, San Jose, CA (US); Dennis R. Pyper, San Jose, CA (US)

(72) Inventors: Shawn X. Arnold, San Jose, CA (US); Dennis R. Pyper, San Jose, CA (US)

(73) Assignee: Apple Incl, Cupertino, CA (US)

(21) Appl. No.: 13/541,427

(22) Filed: Jul. 3, 2012

(51) Int. Cl. H05K 3/46; H05K 1/09; H05K 1/11

(52) U.S. Cl. 174/257; 174/266; 156/60; 156/196; 156/350

(57) ABSTRACT

The described embodiment relates generally to the field of PCB fabrication. More specifically conductive spheres are used in a bonding sheet to enable inter-layer communication in a multi-layer printed circuit board (PCB). The conductive spheres in the bonding sheet can be used in place of or in conjunction with conventional electroplated vias. This allows the following advantages in multi-layer PCB fabrication: dielectric substrate layers made of varying types of material; PCBs with higher resilience to stress and shock; and PCBs that are more flexible.

### BACKGROUND

1. Technical Field

The described embodiment relates generally to the use of conductive balls for transmission of signals through multiple layers of a printed circuit board (PCB).

2. Related Art

Multi-layer PCBs have become ubiquitous in the field of consumer electronics. As the number of layers of these multi-layer PCBs increase so does the number of requisite interconnections between each layer. Most of these inter-layer connections are achieved by running vias between a number of layers in a multi-layer PCB. A via can connect multiple layers by creating a hole in each layer of the multi-layer PCB to be connected. An electro-plating technique is then generally used to create a connection between each layer of the multi-layer PCB. As the number of layers to be plated increases so does the minimum size of the hole created for the via. While electroplated vias accomplish the objective of enabling inter-layer communication between PCB layers, they unfortunately tend to cause structural problems for multi-layer PCBs. Stress testing of Multi-layer PCBs has shown increased rates of failure as a result of stacked vias connecting a number of PCB layers.

Therefore, what is desired is a way to create a more robust and reliable inter-layer connection between layers of a multi-layer PCB.

### SUMMARY OF THE DESCRIBED EMBODIMENTS

This paper describes many embodiments that relate to an apparatus, method and computer readable medium for enabling reliable, robust, and cost effective means for making inter-layer communication in multi-layer PCBs.

In one embodiment of the described embodiment a multi-layer printed circuit board (PCB) is described. The multi-layer PCB includes: (1) a first dielectric substrate layer having a first set of conductive traces and associated vias; (2) a second dielectric substrate layer having a second set of conductive traces and associated vias; and (3) a bonding sheet disposed between and joining the first and second dielectric substrate layers. The bonding sheet includes at least one conductive sphere embedded in the bonding sheet and has a thickness in similar to the at least one conductive sphere. The at least one conductive sphere forms a conductive path between the first set and second set of conductive traces.

In another embodiment a method for manufacturing a multi-layer printed circuit board is described. The method includes the following steps: (1) receiving a first substrate layer having a first set of conductive traces and associated vias; (2) receiving a second substrate layer having a second set of conductive traces and associated vias; (3) receiving a bonding sheet having at least one embedded conductive element; and (4) laminating the first and second substrate layers together to form a multi-layer PCB using the bonding sheet, wherein the at least one embedded conductive element forms a conductive path between the first and second set of conductive traces.

In another embodiment a non-transient computer readable medium for storing computer code executable by a processor is described. The non-transient computer readable medium is used for creating a multi-layer printed circuit board (PCB). The non-transient computer readable medium includes the following pieces of code: (1) computer code for embedding at least one conductive sphere in a bonding sheet; (2) computer code for arranging the bonding sheet between a first and second dielectric substrate layer having a set of electrical traces and associated vias; and (3) computer code for laminating the first and second dielectric substrate layers together to form a multi-layer printed circuit board. During the laminating process the first and second dielectric substrates are conductively coupled through the at least one conductive sphere.

### BRIEF DESCRIPTION OF THE DRAWINGS

The described embodiments and the advantages thereof may best be understood by reference to the following description taken in conjunction with the accompanying drawings. These drawings in no way limit any changes in form and detail that may be made to the described embodiments by one skilled in the art without departing from the spirit and scope of the described embodiments.

FIGS. 1A-1F illustrates conventional methods for enabling inter-layer connections for multi-layer printed circuit boards (PCB);

FIG. 2A illustrates a conductive sphere made from a single metal or metal alloy;

FIG. 2B illustrates a conductive sphere made with a resilient, high temperature, non-conductive core;

FIGS. 3A-3C illustrate how conductive spheres can be quickly inserted into a bonding sheet in accordance with the described embodiment;

FIG. 4 illustrates a perspective view of how a bonding sheet filled with conductive spheres can precisely line up the conductive spheres with inter-layer connectors arranged on multiple dielectric substrate layers;

FIG. 5A illustrates a partial cross-sectional view of a multi-layer PCB in which a conductive sphere is used to complete the inter-layer connection of a through-hole via in accordance with the described embodiment;

FIG. 5B illustrates a partial cross-sectional view of a multi-layer PCB with dielectric substrate layers made from two different dielectric materials;

FIG. 6 illustrates a partial cross-sectional view of a multi-layer PCB with a number of mixed inter-layer connection types;

FIG. 7A illustrates a partial cross-sectional view of a multi-layer PCB in which a conductive sphere is used to enable communication across two blind vias in accordance with the described embodiment;

FIG. 7B illustrates a partial cross-sectional view of a multi-layer PCB subject to a bending force;

FIG. 8 shows a flow chart depicting a process for integrating conductive spheres into the bonding sheet layer of a multi-layer PCB;

FIG. 9 is a block diagram of an electronic device suitable for use with the described embodiments.

### DETAILED DESCRIPTION OF EXAMPLE EMBODIMENTS

A representative apparatus and application of methods according to the present application are described in this section. These examples are being provided solely to add context and aid in the understanding of the described embodiments. It will thus be apparent to one skilled in the art that the described embodiments may be practiced without some or all of these specific details. In other instances, well known process steps have not been described in detail in order to avoid unnecessarily obscuring the described embodiments. Other applications are possible, such that the following examples should not be taken as limiting.

In the following detailed description, references are made to the accompanying drawings, which form a part of the description and in which are shown, by way of illustration, specific embodiments in accordance with the described embodiments. Although these embodiments are described in sufficient detail to enable one skilled in the art to practice the described embodiments, it is understood that these examples are not limiting; such that other embodiments may be used, and changes may be made without departing from the spirit and scope of the described embodiments.

The consumer electronics market has become inundated with increasingly complex electronics. As a result multi-layer PCBs have become ubiquitous in the field of consumer electronics. Multi-layer PCBs allow designers to stack layers of circuitry together minimizing the size and weight of the electronic circuitry. A two layer board can be achieved by etching electrical traces on both sides of a dielectric substrate layer; however, if three or more layers of electrical traces are needed, then additional dielectric substrate layers are laminated together. For example, a four layer board can be produced by etching two layers of electrical traces on each of two dielectric substrate layers and then subsequently laminating the two dielectric substrate layers together by applying an adhesive between the two dielectric substrate layers. The result is that each layer of electrical traces is isolated from every other layer of electrical traces. Two electrical trace layers arranged on opposite sides of a single dielectric substrate layer can be connected by drilling a hole through the dielectric substrate layer and electroplating the hole with copper to electrically connect the two layers of electrical traces. Inter-layer connectors are generally referred to as vias Linking electrical trace layers across multiple dielectric substrate layers generally requires an electroplating process to take place after the associated dielectric substrate layers have been laminated together. Unfortunately, as the number of dielectric substrate layers to be plated through increases so does the minimum size of the hole created for the via. These larger via holes running through multiple dielectric board layers can take up valuable dielectric substrate layer surface area, limiting space for routing traces across each electrical trace layer. Furthermore, since the inter-layer vias are stacked on top of each other board designers have to clear space in the same place on each electrical trace layer to make room to create such a connection, constraining electrical trace routing even more. Moreover, stress and shock testing have shown that by stacking multiple via holes on top of each other the resulting multi-layer PCB becomes more fragile resulting in a higher incidence of structural integrity failures. So, while these inter-layer vias accomplish the objective of enabling inter-layer communication between PCB layers, other more structurally sound methods for accomplishing inter-layer connections are highly desirable.

One solution to the previously described problems is to add conductive pathways into the adhesive layer. Conductive pathways in the adhesive layer can enable communication through the adhesive layer without having to perform an electroplating process through the adhesive layer. These conductive pathways embedded in the adhesive layer can result in significant time and cost saving when compared to conventional electroplating processes. However, when an adhesive layer is used to bind two dielectric substrate layers together a liquid adhesive is generally used making precise placement of the conductive pathway problematic at best. Instead of applying an adhesive layer directly to the board, a solid bonding sheet can be preformed to match the volume of adhesive required and to match the shape of the dielectric substrate layer to which it is to be applied. The bonding sheet can be a solidified, uncured fiberglass matrix pre-impregnated with epoxy. At temperatures below or at about room temperature such a bonding sheet can maintain its formed shape and size.

Connection holes can then be drilled or punched into the bonding sheet. The connection holes can then be filled with conductive elements of appropriate size and shape. For example, in a particularly useful configuration, the conductive elements can have an overall spherical or spheroidal shape sized to snugly fit into the connection holes The connection holes can be filled with the conductive elements in any of a number of ways including for example: (1) a vibration table and brush for settling conductive spheres into the connection holes; (2) a suction system used to arrange the conductive elements in a pattern corresponding to the connection holes at which point the conductive elements can be pressed into the corresponding connection holes; or (3) a pick and place designed to press the conductive elements into the dielectric substrate layer one at a time. The conductive elements can form the previously referenced conductive pathway. In this way the conductive pathways can be aligned precisely with electrical trace connections located on the dielectric substrate layers to which the bonding sheet attaches. In one embodiment the conductive elements can be made entirely of copper, while in other embodiments the conductive elements can be made entirely from solder. In yet another embodiment the conductive elements can have a solid high temperature plastic core with an outer layer of solder. When the conductive pathways are established with conductive elements having nonconductive cores, a reduction in electrical resistance can be achieved providing an improved signal and reduced heat loss. The material composition of the bonding sheet can be designed to cure at a temperature which corresponds to the temperature at which metal from an outer surface of the conductive elements becomes soft enough to adhere to adjoining conductive pathway connections. In this way when the dielectric substrate layers are laminated together, conductive pathways are also established through the bonding sheet without the need for a subsequent step of electroplating through two or more dielectric substrate layers.

In certain embodiments a flexible multi-layer PCB is desirable. Since the placement of conductive elements in the adhesion layer can effectively break up somewhat rigid vias that in some cases had to extend through every layer of a multi-layer PCB, the described embodiment can result in increases in board flexibility. Because dielectric substrate layers are no longer rigidly joined, the multi-layer PCB can be more easily manipulated. This is particularly the case during a lamination process. During the lamination process the surface consistency of the conductive elements can be softened, allowing stresses on inter-layer connections to be minimized during the shaping process. Consequently, the described embodiment can allow for higher reliability in boards that undergo reshaping as part of a manufacturing process.

Another benefit of the described embodiment is the ability to construct a multi-layer PCB having layers made of different materials. Multi-layer PCB manufacturers generally construct multi-layer PCBs from a single type of dielectric substrate layer. When using conventional manufacturing methods variations in materials used to construct dielectric substrate layers can cause additional thermal stresses during thermal loading. This can cause an undue amount of stress on rigid inter-layer connections leading to untimely and highly undesirable early failure rates in multi-layer PCBs. The ability to forego rigid interlayer connections extending through multiple dielectric substrate layers can ease stresses caused by variations in thermal expansion properties. This stress reduction is particularly effective in cases where a somewhat resilient conductive element is used for inter-layer connections; the more resilient conductive element can act as a buffer or stress reliever between the layers, ameliorating thermal stresses that would otherwise be caused by recurring thermal excursions.

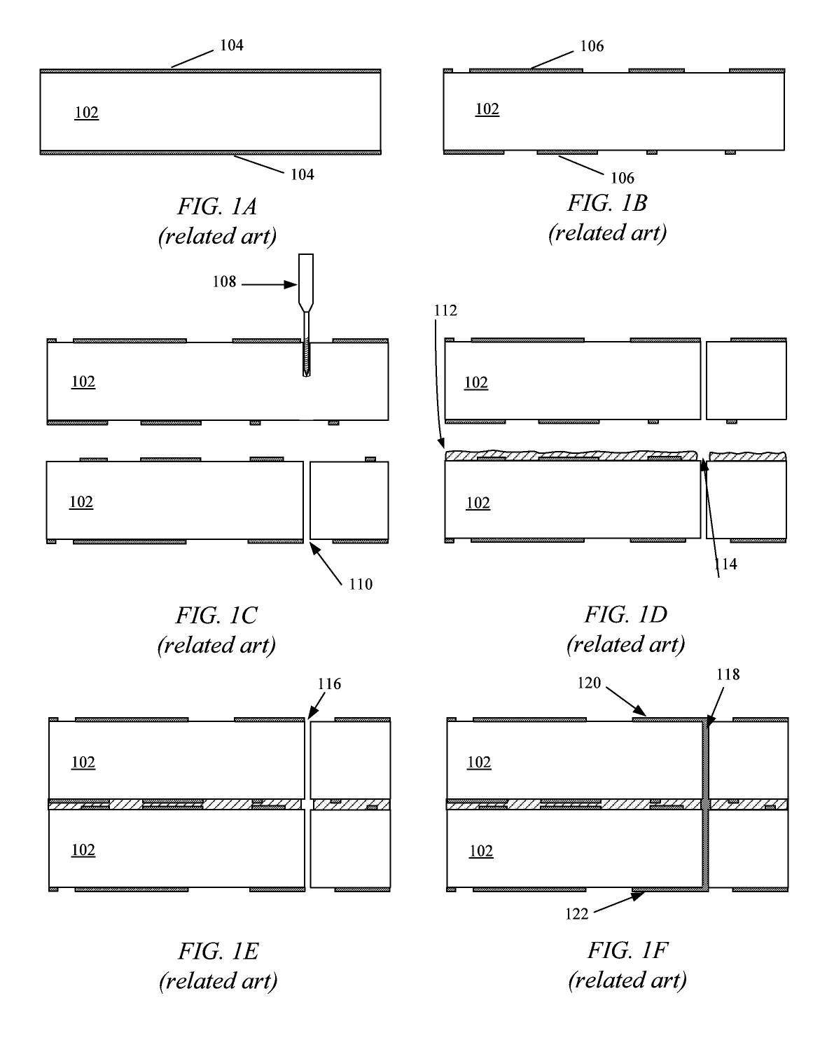

These and other embodiments are discussed below with reference to FIGS. 1-11; however, those skilled in the art will readily appreciate that the detailed description given herein with respect to these figures is for explanatory purposes only and should not be construed as limiting.

FIGS. 1A-1F shows a conventional approach for fabricating a multi-layer PCB. In FIG. 1A a dielectric substrate layer 102 is overlaid with copper foil layers 104. Copper foil layers 104 can be of varying thickness depending on the amount of current a particular layer of the resulting multi-layer PCB will carry. In FIG. 1B electrical trace layer 106 is formed by applying a chemical etch to a masked copper foil layer 104. This process will take place with each layer of the multi-layer PCB. In FIG. 1C two dielectric substrate layers 102 are shown. Drill bit 108 is shown drilling a hole in dielectric substrate layer 102. Via holes 110 may be created by a mechanical drill as shown, or with a laser cutter. Via holes 110 in dielectric boards 102 must line up for a multi-substrate layer via to be created. The more layers the board has the thicker via hole 110 must be to enable the resulting hole to be electroplated all the way through the board. Thicker via holes 110 also result in a loss of surface area on each board layer that they pass through. Thicker via holes also tend to reduce the structural integrity of the resulting multi-layer PCB. In FIG. 1D adhesive layer 112 is applied to an upper surface of dielectric substrate 102 for laminating the two dielectric substrate layers together. The entry to via holes 110 can be masked off when applying adhesive layer 112, resulting in adhesive gap 114. FIG. 1E shows the two dielectric substrate layers pressed together against bonding sheet 112. At this point heat is generally applied to cure adhesive layer 112 and solidify the connection between dielectric substrate layers 102. After the lamination process is complete via hole 116 is created running through the resulting multi-layer PCB. Finally, in FIG. 1F an electroplating process can be used to create via 118. Via 118 is generally made of copper plating adhered to the surface of via hole 116. In this multi-layer PCB via 118 creates an electrical connection between electrical trace 120 located on the upper surface of the multi-layer PCB and electrical trace 122 located on the lower surface of the multi-layer board. While these vias accomplish the objective of enabling inter-layer communication between dielectric substrate layers, they unfortunately tend to cause structural problems for multi-layer PCBs. Stress testing of multi-layer PCBs has shown increased rates of failure around conventional vias extending through multiple dielectric substrate layers. Therefore, other more structurally sound methods for accomplishing interlayer connections are highly desirable.

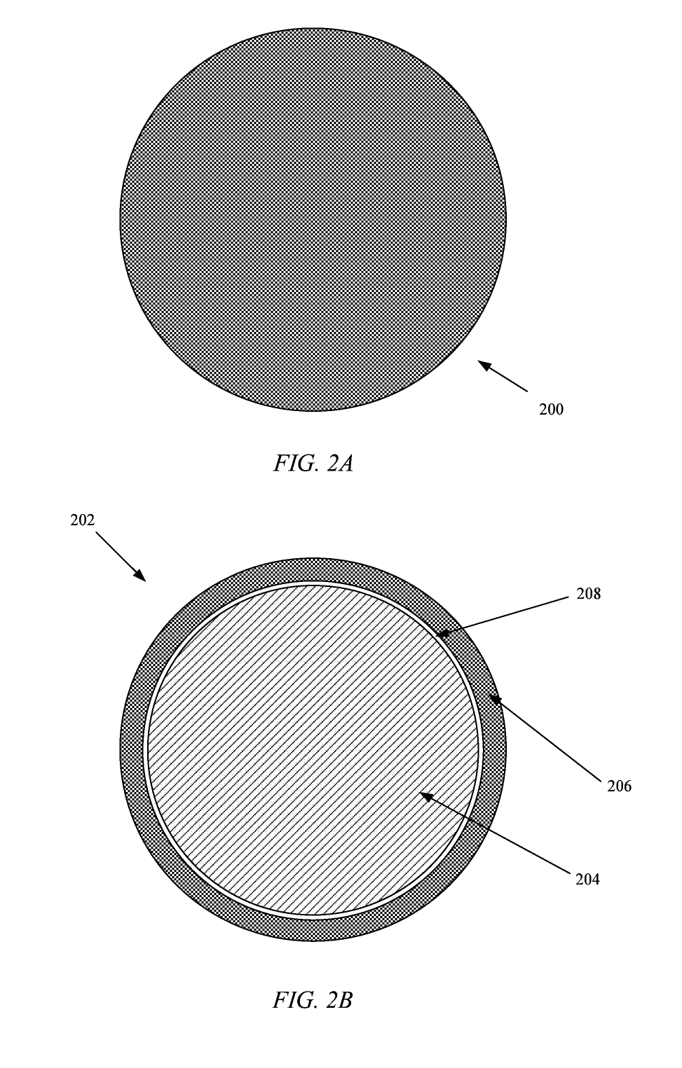

FIGS. 2A and 2B show two embodiments of a conductive element that for the remainder of this discussion is presumed to be spherical or spheroidal in shape and is henceforth referred to as a conductive sphere. It should be noted, however, that the conductive element can take on any appropriate size and shape. It also should be noted that a conductive sphere can be solid (as in FIG. 2A) or include a non-conductive core (as in FIG. 2B) that when compared to the solid conductive sphere has less overall electrical resistance. This lower electrical resistance can be quite advantageous. For example, the lowered electrical resistance can result in reducing the generation of excess heat. In any case, either form of the conductive spheres can be generally useful in quickly filling a known volume with conductive material.

FIG. 2A shows conductive sphere 200 formed of a uniform material such as pure metal or metal alloy along the lines of copper or solder. Copper can be used in situations where solder might be undesirable due to solder's inability to maintain its shape at certain operating temperatures. Generally, electrical connections for solid copper spheres can be made by laser plating the solid copper sphere to an electrical trace, or filled copper via. Laser plating allows manufacturers to conduct localized heating on for example a copper conductive sphere causing a portion of an exterior portion of the conductive sphere to melt, thereby creating a conductive pathway to nearby conductors. FIG. 2B shows another embodiment of a conductive element in the form of conductive sphere 202 having solid core 204. In the described embodiments, solid core 204 can be made of a heat resistant material such as high temperature plastic along the lines of divinylbenzene copolymer. In this way, the overall weight of conductive sphere 202 can be substantially reduced compared to the overall weight of conductive sphere 200. Furthermore, solid core 204 formed of high temperature plastic can also advantageously provide more structural resilience (i.e., higher modulus of elasticity) to conductive sphere 202. An example of conductive sphere 202 is trade named Micropearl™ and is manufactured by Sekisui Chemical Co. of Japan and is commercially available in sizes between 40 and 800 microns. In applications where it is desirable to maintain a spherical shape, solid core 204 can help conductive sphere 202 maintain that spherical shape. In addition to solid core 204, conductive sphere 202 can include first solder layer 206 that can temporarily liquefy during a bonding operation thereby providing a mechanism for forming a reliable conductive pathway between conductive sphere 202 and external electrical conductors. In addition to, or in place of first solder layer 206, conductive sphere 202 can also second conductive layer 208 made of a conducting material such as copper. Since copper melts at a higher temperature than most solder composites, second conductive layer 208 can help maintain the overall conductivity of conductive sphere 202 even if portions of first solder layer 206 wick away from the surface of conductive sphere 202 to expose second conductive layer 208.

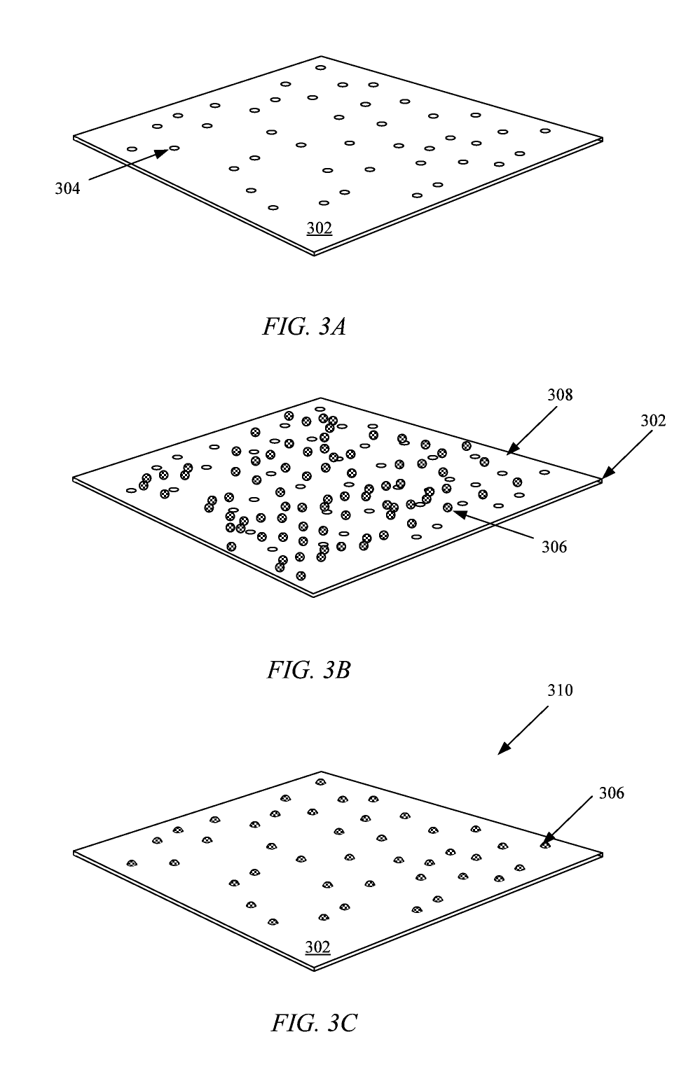

FIGS. 3A-3C illustrate how conductive spheres can be embedded into a bonding sheet. In FIG. 3A bonding sheet 302 is shown with a number of connection holes 304. Bonding sheet 302 can be made of material having adhesive properties sufficient to bond together two layers of a multi-layer PCB. In one implementation, bonding sheet 302 can be a pre-impregnated (pre-preg) material containing epoxy mixed into a fiberglass matrix. Bonding sheet 302 can be stored at a cool temperature to keep it in a solidified state before being heated and cured between dielectric substrate layers. Connection holes 304 can be formed in any suitable manner For example, connection holes 304 can be formed by mechanically drilling, punching or laser cutting through bonding sheet 302. In other embodiments connection holes 304 can be formed as part of a bonding sheet molding process in which case connection holes 304 can be formed by a mold used to create bonding sheet 302. Connection holes 304 can be arranged in a pattern which corresponds to inter-layer connections in a resulting multi-layer PCB. Connection hole 304 can be substantially the same size and same shape as a corresponding conductive elements each having a about the same size and shape. For example, using a spherical shaped conductive element (such as solid conductive sphere 200 or 202) each of connection holes 304 have corresponding shape but a somewhat smaller diameter as the corresponding conductive sphere. In this way, a particular conductive sphere can snugly fit into a corresponding connection hole. The size relationship between connection holes 304 and conductive spheres 200, 202 can be the basis for an efficient insertion process known as a micro-ball process shown in FIG. 3B.

FIG. 3B as part of a micro-ball process a number of conductive spheres 306 can be released on surface 308 of bonding sheet 302. In one embodiment, a plurality of conductive spheres can be released onto surface 308 of bonding sheet 302 that is in contact with a motion source, such as a vibration table (not shown) that shakes bonding sheet 302. The motion of bonding sheet 302 causes the released conductive spheres to move about surface 308. In one embodiment, an external agent such as a brush can accelerate the motion of the conductive spheres across the surface of bonding sheet 302 until all (or at least most) of connection holes 304 are filled with a conductive sphere 306. It should be noted that the brush can apply an insertion force that “press fits” the conductive sphere into the somewhat undersized (in relation to the sphere) hole providing a good mechanical support. In another embodiment a vacuum can be provided that draws conductive spheres to a corresponding hole (the pressure differential can provide the requisite insertion force). In yet another embodiment, a mechanical apparatus such as a pick and place machine can be used to arrange conductive sphere 306 in each connection hole 304. In some embodiments, conductive spheres 306 can generally have a diameter about equal to the thickness of bonding sheet 302. FIG. 3C shows embedded bonding sheet 310 populated with conductive spheres 306 in each connection hole 304 in bonding sheet 302. Embedded bonding sheet 310 can be stored at a cool temperature until ready for use in a manufacturing operation.

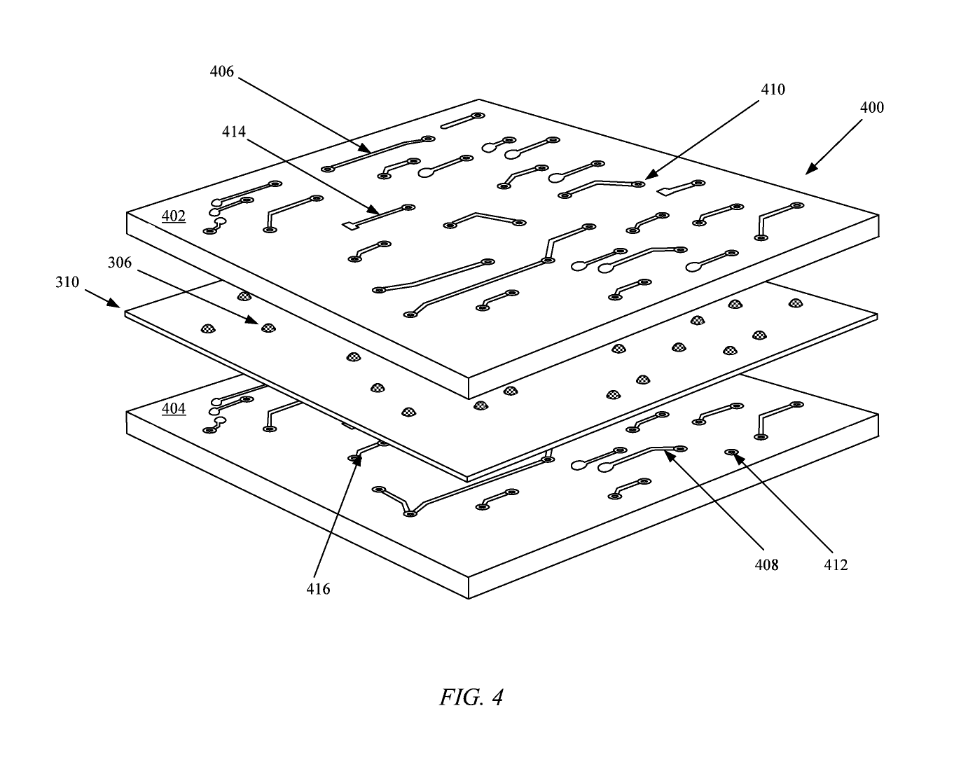

FIG. 4 shows system 400 that includes embedded bonding sheet 310 positioned between first dielectric substrate layer 402 and second dielectric substrate layer 404. Dielectric substrate layers 402, 404 can have electrical traces 406, 408 running along both their respective upper and lower surfaces. Dielectric substrate layers 402, 404 can also have electroplated via holes 410, 412 some of which align with conductive spheres 306 and with each other whereas others of conductive spheres 306 can align with conductive pathway connectors 414, 416 found on some of electrical traces 406, 408. Embedded bonding sheet 310 can be used to attach dielectric substrate layers 402, 404 together in a lamination process. In some embodiments heat required for the lamination process can cause a surface portion of conductive spheres 306 to liquefy (if formed of solder, for example) to connect with their corresponding connections. In other embodiments (when the conductive spheres are fully formed of copper, for example) an additional step such as laser plating can be required to bond conductive spheres to their corresponding connections. Since embedded bonding sheet 310 fixes the position of conductive spheres 306, positioning of conductive spheres 306 between dielectric substrate layers 402, 404 can also be well defined. Another advantage of the described embodiment is that, the diameter of conductive spheres 306 can help to establish a minimum distance between dielectric substrate layers 402, 404. In this way, a designer can use the conductive spheres to maintain a set distance between adjacent dielectric substrate layers thereby preventing the substrate layers from getting too close to each other. In this way shorts between dielectric substrate layers 402, 404 can be substantially prevented by a matrix of conductive spheres 306 keeping dielectric substrate layers 402 a minimum distance apart.

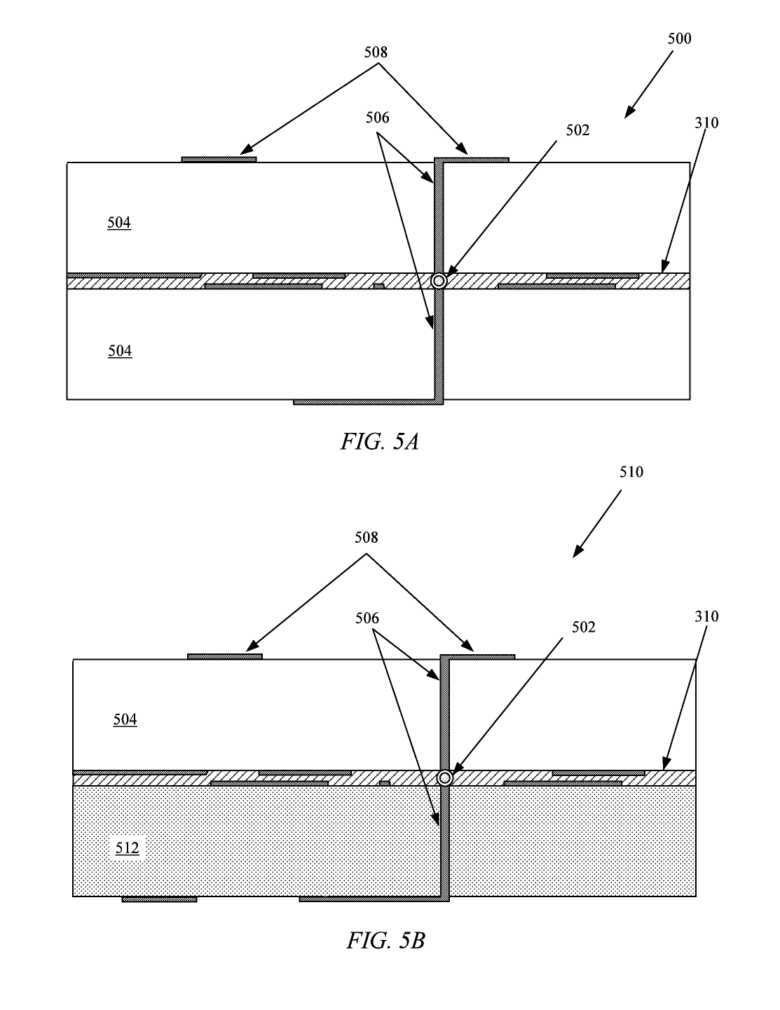

FIGS. 5A and 5B show a partial cross-section of a multi-layer PCB 500 with two dielectric substrate layers. In this particular embodiment of the described embodiment embedded bonding sheet 310 includes conductive sphere 502 that is placed in such as way to form an inter-layer connection between dielectric substrate layers 504 by way of via 506. Because conductive sphere 502 is used to create the inter-layer connection for via 506, the electroplating process can be completed before dielectric substrate layers 504 are joined together. Since the electroplating process need only be applied through one layer at a time, the hole for through-hole via 506 can generally be smaller in diameter leaving more available board level real estate to position electrical traces 508. This also allows individual board layers to be assembled and finished before being attached together.

FIG. 5B shows PCB 510 in which at least two dielectric substrate layers 504 and 512 are made of two different materials having different properties. For example, PCBs formed of low cost dielectric materials such as FR4 (FR-4 is a composite material formed of woven fiberglass cloth with an epoxy resin binder) tend to have different properties than those formed of dielectric materials that although more expensive allow for cleaner transmission of high frequency signals. By taking advantage of the lower cost of FR-4, the cost of some multi-layer PCBs can be reduced by building only certain layers (those most affected by high frequency noise, for example) out of more costly materials. The advantages of these multi-material boards (such as the one shown in FIG. 5B) can be outweigh in conventional PCB manufacture due to the vias bridging dissimilar PCB layers can be compromised by factors such as dissimilar thermal expansion rates. However, by using conductive sphere 502 having a solid yet resilient core, shearing forces applied to the connection can be substantially reduced by the higher flexibility of for example a plastic core. This results in a higher reliability bond between the two dissimilar materials, since the more flexible solder joint can be more resilient to thermal fatigue. In this way designers can have much more flexibility in choosing a variety of materials when designing multi-layer PCBs.

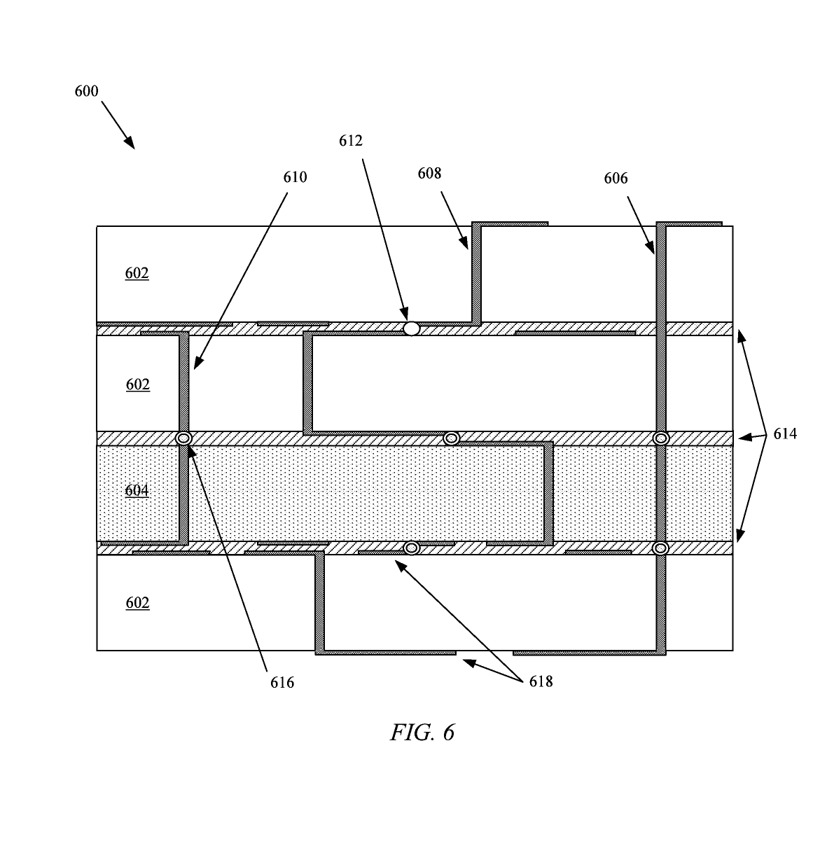

FIG. 6 illustrates multi-layer PCB 600 having a total of four dielectric substrate layers. Multi-layer PCB 600 has 3 dielectric substrate layers 602 made from one material and one dielectric substrate layer 604 made from another material. A higher cost material might be necessary for carrying high frequency signals along dielectric substrate layer 604. The described embodiment allows a cost savings since it allows the dielectric substrate layers to include different dielectric materials. FIG. 6 shows how a number of different types of vias can be combined to route signals through a multi-layer PCB 600. Vias are typically classified into three categories. Via 606 is an example of a through-hole via. A through-hole vias extend from one side of multi-layer PCB 600 to the other. Via 608 is an example of a blind via. A blind via which extends from an outer layer of multi-layer PCB 600 to an inner layer of a multi-layer PCB 600. Via 610 is an example of a buried via. A buried via connects inner layers of a multi-layer PCB 600. As shown in FIG. 6 conductive spheres 612 embedded in one of bonding sheets 614 can be used as a conductive pathway enabling inter-layer communications between blind vias. Conductive sphere 616 in this illustration is used to connect a buried via. It should also be noted that conductive sphere 612 is illustrated as a solid conductive sphere as described in FIG. 2A, as opposed to conductive sphere 616 which is illustrated as a conductive sphere with a non-conductive core. This illustration therefore shows that conductive spheres of different types can be used in the same multi-layer PCB. This might be advantageous where a conductive sphere having a higher melting temperature was needed in a part of the multi-layer PCB which was expected to undergo more extreme thermal excursions. FIG. 6 shows dielectric substrate layer 604 arranged as an inner layer. By using conductive spheres as opposed to conventional electroplated vias along both surfaces of dielectric substrate layer 604 the effect of any differences in thermal expansion between dielectric substrate layers 604 and 602 can be minimized As thermal expansion or thermal excursions take place resulting thermal fatigue on the vias can be mitigated by the resilience of conductive spheres 612.

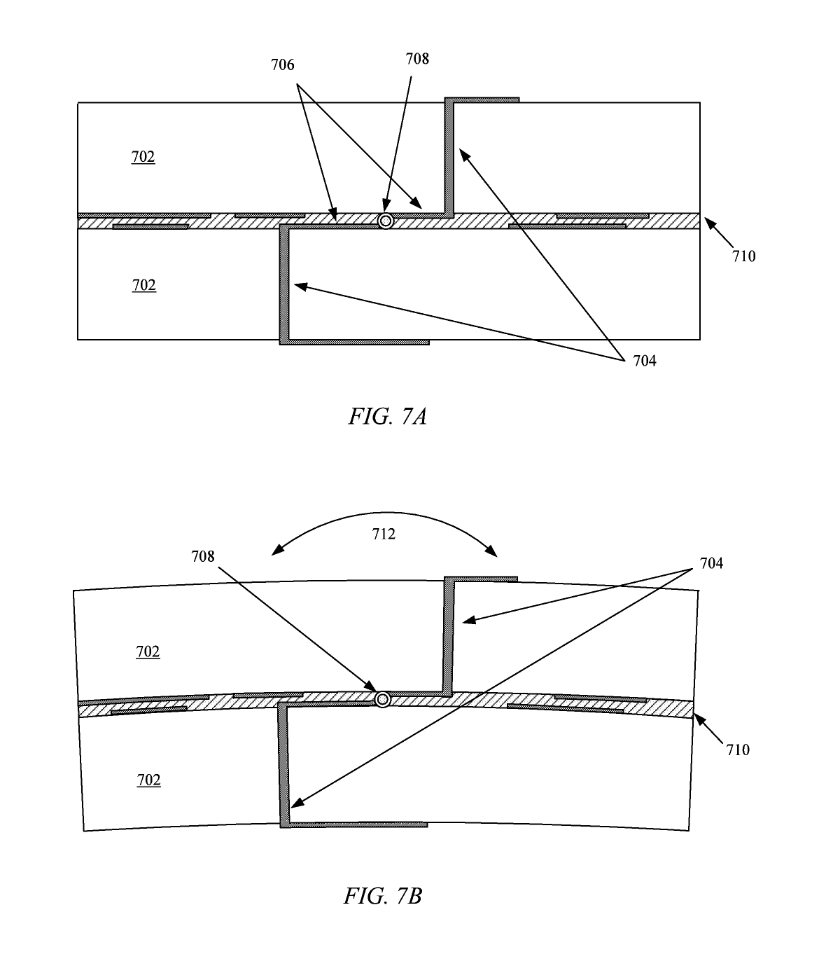

FIGS. 7A and 7B show how conductive spheres can be used to link blind vias (vias on different layers that do not align with each other). Standard fabrication techniques don't generally allow for blind vias to be connected. By integrating conductive spheres into the bonding sheet this can change. In FIG. 7A a circuit board with dielectric substrate layers 702 is shown with a set of blind vias 704. Blind vias 704 can be connected by electrical traces 706 which are connected by conductive sphere 708. This may be preferable to configurations in which holes for vias must be aligned. It should be apparent that this technique can also be used for the simpler task of connecting two elements on opposite sides of bonding sheet 710. Stress tests have shown aligned via holes can have an adverse affect on the ultimate integrity of a multi-layer PCB. Therefore, in applications where board strength is important, a configuration in which blind vias can be linked is advantageous as it tends to increase the reliability of the resultant board when compared to a board with stacked via holes.

FIG. 7B shows another advantage of using conductive spheres 708. In this example after dielectric substrate layers 702 are joined together and during a curing operation on the multi-layer PCB a bending force 712 can be applied to the board. Since blind vias 704 are not directly linked there is no shearing force created between the two vias 704, and since bonding sheet 710 is being heated it is somewhat pliable; therefore, any inter-layer forces are substantially mitigated by the described configuration. Bending a multi-layer PCB as described can be desirable in situations in which a board needs to follow the contour of a spline shaped enclosure, or be situated around some other component in a larger electronic device. Conductive spheres 708 can also be inserted into bonding sheet 710 only in areas of the multi-layer PCB that would be subject to bending. In this way a multi-layer PCB can be rigid in some areas and more flexible in other areas where a shaping operation can take place. For example, a mix of conventional vias and vias in accordance with the described embodiment could be used to create a board with both flexible and rigid regions.

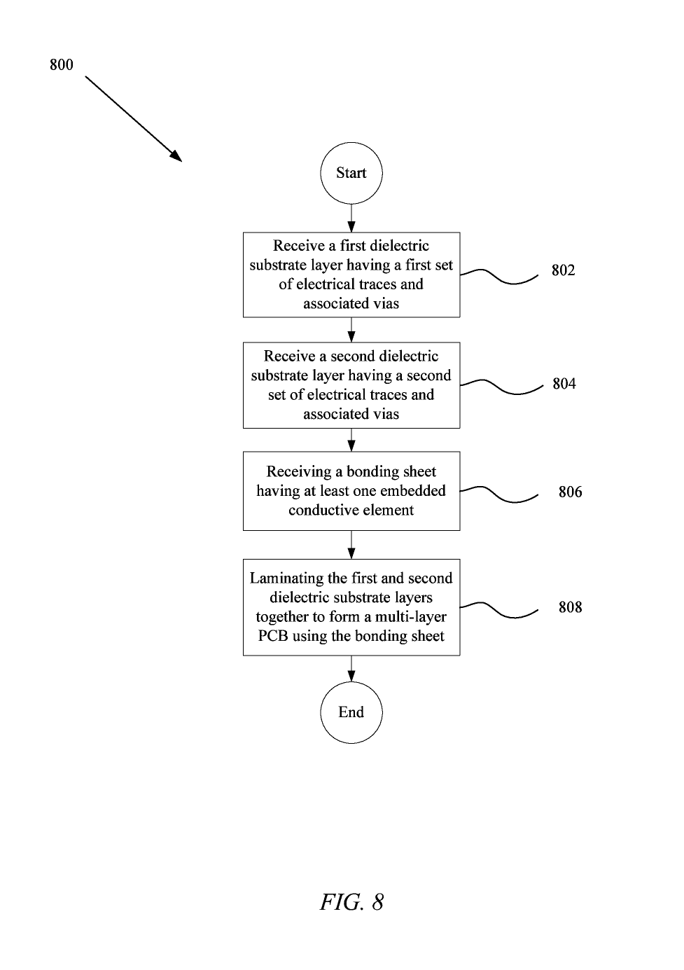

FIG. 8 shows a flow chart depicting process 800 for integrating conductive spheres into the bonding sheet layer. Process 800 can be carried out by receiving a first dielectric substrate layer having a first set of electrical traces and vias at 802. A second dielectric substrate layer is then received having a first set of electrical traces and vias at 804. Both dielectric substrate layers can have electrical traces running on one or both of their surface layers. The first and second layer will be combined by adhering them together with a bonding sheet. That bonding sheet can have at least one embedded conductive element and is received at 806. In some embodiments the conductive element can be a conductive sphere. The conductive sphere can be made of a solid metal such as copper, or a solidified solder ball. Alternatively the conductive sphere can have a non-conductive, high temperature resistant, resilient core surrounded by a layer of solder. In yet another embodiments a number of conductive spheres can be embedded in a pre-planned pattern corresponding to inter-layer conductive paths between the first and second dielectric substrate layers. At 808 the first and second dielectric substrate layers are laminated together to form a multi-layer PCB. Because the bonding sheet holds the conductive spheres firmly in place each conductive sphere can be precisely arranged to make contact with the inter-layer connectors found on electrical traces or vias arranged on the first and second Dielectric substrate layers. In some embodiments the laminating process will also cause the conductive spheres to bond with the inter-layer connectors found on each layer, while in other embodiments an additional localized heating step can be applied such as laser plating to solidify connections between the conductive spheres and the inter-layer connectors.

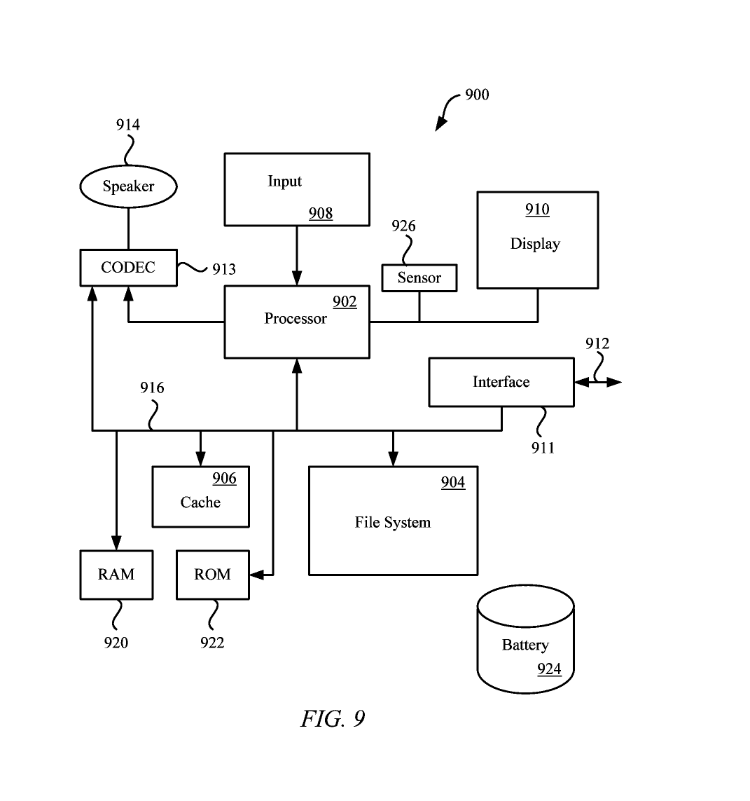

FIG. 9 is a block diagram of electronic device 900 suitable for controlling some of the processes in the described embodiment. Electronic device 900 illustrates circuitry of a representative computing device. Electronic device 900 includes a processor 902 that pertains to a microprocessor or controller for controlling the overall operation of electronic device 900. Electronic device 900 contains instruction data pertaining to manufacturing instructions in a file system 904 and a cache 906. The file system 904 is, typically, a storage disk or a plurality of disks. The file system 904 typically provides high capacity storage capability for the electronic device 900. However, since the access time to the file system 904 is relatively slow, the electronic device 900 can also include a cache 906. The cache 906 is, for example, Random-Access Memory (RAM) provided by semiconductor memory. The relative access time to the cache 906 is substantially shorter than for the file system 904. However, the cache 906 does not have the large storage capacity of the file system 904. Further, the file system 904, when active, consumes more power than does the cache 906. The power consumption is often a concern when the electronic device 900 is a portable device that is powered by a battery 924. The electronic device 900 can also include a RAM 920 and a Read-Only Memory (ROM) 922. The ROM 922 can store programs, utilities or processes to be executed in a non-volatile manner. The RAM 920 provides volatile data storage, such as for cache 906.

The electronic device 900 also includes a user input device 908 that allows a user of the electronic device 900 to interact with the electronic device 900. For example, the user input device 908 can take a variety of forms, such as a button, keypad, dial, touch screen, audio input interface, visual/image capture input interface, input in the form of sensor data, etc. Still further, the electronic device 900 includes a display 910 (screen display) that can be controlled by the processor 902 to display information to the user. A data bus 916 can facilitate data transfer between at least the file system 904, the cache 906, the processor 902, and a CODEC 913. The CODEC 913 can be used to decode and play a plurality of media items from file system 904 that can correspond to certain activities taking place during a particular manufacturing process. The processor 902, upon a certain manufacturing event occurring, supplies the media data (e.g., audio file) for the particular media item to a coder/decoder (CODEC) 913. The CODEC 913 then produces analog output signals for a speaker 914. The speaker 914 can be a speaker internal to the electronic device 900 or external to the electronic device 650. For example, headphones or earphones that connect to the electronic device 900 would be considered an external speaker.

The electronic device 900 also includes a network/bus interface 911 that couples to a data link 662. The data link 912 allows the electronic device 900 to couple to a host computer or to accessory devices. The data link 912 can be provided over a wired connection or a wireless connection. In the case of a wireless connection, the network/bus interface 911 can include a wireless transceiver. The media items (media assets) can pertain to one or more different types of media content. In one embodiment, the media items are audio tracks (e.g., songs, audio books, and podcasts). In another embodiment, the media items are images (e.g., photos). However, in other embodiments, the media items can be any combination of audio, graphical or visual content. Sensor 926 can take the form of circuitry for detecting any number of stimuli. For example, sensor 926 can include any number of sensors for monitoring a manufacturing operation such as for example a Hall Effect sensor responsive to external magnetic field, an audio sensor, a light sensor such as a photometer, and so on.

The various aspects, embodiments, implementations or features of the described embodiments can be used separately or in any combination. Various aspects of the described embodiments can be implemented by software, hardware or a combination of hardware and software. The described embodiments can also be embodied as computer readable code on a computer readable medium for controlling manufacturing operations or as computer readable code on a computer readable medium for controlling a manufacturing line. The computer readable medium is any data storage device that can store data which can thereafter be read by a computer system. Examples of the computer readable medium include read-only memory, random-access memory, CD-ROMs, DVDs, magnetic tape, and optical data storage devices. The computer readable medium can also be distributed over network-coupled computer systems so that the computer readable code is stored and executed in a distributed fashion.

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of specific embodiments are presented for purposes of illustration and description. They are not intended to be exhaustive or to limit the described embodiments to the precise forms disclosed. It will be apparent to one of ordinary skill in the art that many modifications and variations are possible in view of the above teachings.

What is claimed is:

1. A multi-layer printed circuit board (PCB), comprising:
a first dielectric substrate layer having a first set of conductive traces and associated vias;
a second dielectric substrate layer having a second set of conductive traces and associated vias; and
a bonding sheet disposed between and joining the first and second dielectric substrate layers, the bonding sheet comprising at least one hole in which is located a discreet conductive element having a size and shape that corresponds to a size and shape of the at least one hole,
wherein the at least discreet conductive element forms a conductive path between the first set and second set of conductive traces.

2. The multi-layer PCB of claim 1, wherein the at least one conductive element is a conductive sphere.

3. The multi-layer PCB of claim 2, wherein the conductive sphere is formed of solid copper, wherein the conductive path is formed by a laser plating process.

4. The multi-layer PCB of claim 2, wherein the conductive sphere comprises a non-conductive core and a conductive outer layer.

5. The multi-layer PCB of claim 2, wherein the conductive sphere establishes a fixed minimum distance between the first and second dielectric substrate layers.

6. The multi-layer PCB of claim 1, wherein the first dielectric substrate layer is comprised of a different material than the second dielectric substrate layer.

7. The multi-layer PCB of claim 2, wherein during a molding operation, the bonding sheet and the at least one connection hole corresponding to the position of the at least one conductive sphere are formed.

8. The multi-layer PCB of claim 2, wherein the at least one conductive sphere is between 40 and 500 microns in diameter.

9. A method for manufacturing a multi-layer printed circuit board, comprising:
receiving a first substrate layer having a first set of conductive traces and associated vias;
receiving a second substrate layer having a second set of conductive traces and associated vias;
receiving a bonding sheet having at least one embedded conductive element; and
laminating the first and second substrate layers together to form a multi-layer PCB using the bonding sheet,
wherein the at least one embedded conductive element forms a conductive path between the first and second set of conductive traces.

10. The method as recited in claim 9 wherein the bonding sheet is comprised of a fiber glass matrix pre-impregnated with epoxy resin and is kept in a solidified state prior to being laminated between the first and second dielectric substrate layers.

11. The method as recited in claim 10 wherein the embedded conductive element is a conductive sphere.

12. The method as recited in claim 11, wherein during the laminating step a portion of an exterior surface of the conductive spheres melts and subsequently solidifies thereby setting the connections in the conductive pathway between the first and second dielectric substrate layers.

13. The method as recited in claim 12, wherein the first substrate layer is made of a different material than the second substrate layer.

14. The method as recited in claim 9, further comprising:
applying a shaping force to the multi-layer PCB while the bonding sheet is still pliable from the lamination process, wherein the shaping force causes the multi-layer PCB to assume a new shape.

15. A non-transient computer readable medium for storing computer code executable by a processor in a computer aided manufacturing system for creating a multi-layer printed circuit board (PCB), comprising:
computer code for embedding at least one conductive sphere in a bonding sheet;
computer code for arranging the bonding sheet between a first and second dielectric substrate layer having a set of electrical traces and associated vias; and
computer code for laminating the first and second dielectric substrate layers together to form a multi-layer printed circuit board,
wherein during the laminating process the first and second dielectric substrates are conductively coupled through the at least one conductive sphere.

16. The non-transient computer readable medium as recited in claim 15, wherein a plurality of dielectric substrate layers are laminated to the created multi-layer PCB.

17. The non-transient computer readable medium as recited in claim 16, wherein the at least one conductive sphere embedded in the bonding sheet joins a plurality of electroplated vias which form conductive pathways throughout the plurality of substrate layers.

18. The non-transient computer readable medium as recited in claim 17, wherein the at least one conductive sphere is embedded into the bonding sheet using a vibration table and brush.

19. The non-transient computer readable medium as recited in claim 17, wherein a surface portion of the at least one conductive sphere melts and solidifies against adjacent corresponding electrical traces during the laminating process.
